(19) United States
(12) Patent Application Publication
(10) Pub. No.: US 2011/0271994 A1
(43) Pub. Date: Nov. 10, 2011

(54) Hot Side Heat Exchanger Design And Materials

(75) Inventor: Michael D. Gilley, Rowlett, TX (US)

(73) Assignee: Marlow Industries, Inc., Dallas, TX (US)

(21) Appl. No.: 13/100,918

(22) Filed: May 4, 2011

Related U.S. Application Data
(60) Provisional application No. 61/331,569, filed on May 5, 2010.
(60) Provisional application No. 61/331,564, filed on May 5, 2010.

(51) Int. Cl. H01L 35/30; B21D 53/02; F28F 7/00

(52) U.S. Cl. 136/205; 165/185; 29/890.03

(57) ABSTRACT

In certain embodiments, a hot side heat exchanger (HSHX) includes a folded fin structure including a plurality of fins. Each of the plurality of fins is formed from a composite fin material having a first fin layer positioned between a second fin layer and a third fin layer, the first fin layer being a first material and the second and third fin layers being a second material. A base plate is in thermal communication with the plurality of folded fins. The base plate is formed from a composite base plate material having a first base plate layer and a second base plate layer, the first base plate layer being a first material and the second base plate layer being the second material. The first material has a greater thermal conductivity than the second material and the second material has greater corrosion resistance and high temperature strength than the first material.

### RELATED APPLICATIONS

This application claims the benefit of U.S. Provisional Application No. 61/331,569, titled “HOT SIDE HEAT EXCHANGER DESIGN AND MATERIALS”, filed on 5 May 2010 and U.S. Provisional Application No. 61/331,564, titled “THREE DIMENSIONAL THERMOELECTRIC GENERATOR/HEAT EXCHANGER ARRAY HAVING A LEAF SPRING CLAMPING ASSEMBLY,” both of which are incorporated herein in their entirety.

### GOVERNMENT RIGHTS

A portion or all of this disclosure may have been made with Government support under government contract number DAAB07-03-D-B009, awarded by the United States Army of the United States Department of Defense. The Government may have certain rights in this disclosure.

### TECHNICAL FIELD

This disclosure relates generally to heat exchangers and more particularly to a hot side heat exchanger (HSHX) design and materials.

### BACKGROUND

The basic theory and operation of certain thermoelectric generators has been developed for many years. Presently available thermoelectric generators used for power generation applications typically include an array of electrically-interconnected thermoelectric elements which operate in accordance with the Peltier effect. In a typical thermoelectric generator, the array of thermoelectric elements may be coupled between a pair of ceramic plates. When a temperature difference is applied to the ceramic plates (e.g., when one of the ceramic plates is heated) a voltage develops across the thermoelectric elements. This electrical energy may be drawn from the device through a pair of electrical leads that are electrically connected to the thermoelectric elements. Through this process, thermoelectric generators are able to convert thermal energy (i.e., temperature differences) into electrical energy.

### SUMMARY

According to the present disclosure, disadvantages and problems associated with previous HSHX designs and materials may be reduced or eliminated.

In certain embodiments, a HSHX includes a folded fin structure including a plurality of fins. Each of the plurality of fins is formed from a composite fin material having a first fin layer positioned between a second fin layer and a third fin layer, the first fin layer being a first material and the second and third fin layers being a second material. The hot side heat exchanger also includes a base plate in thermal communication with the plurality of folded fins of the folded fin structure. The base plate is formed from a composite base plate material having a first base plate layer and a second base plate layer, the first base plate layer being a first material and the second base plate layer being the second material. The first material has a greater thermal conductivity than the second material and the second material has greater corrosion resistance and high temperature strength than the first material.

Certain embodiments of the present disclosure may provide one or more technical advantages. A HSHX being formed from materials having high corrosion resistance and high temperature strength may be important in waste heat recovery applications as the environment from which waste heat is recovered (e.g., an exhaust stream of a vehicle) may include both high temperatures and corrosive gasses. Materials having high corrosion resistance and high temperature strength (e.g., stainless steel), however, may have thermal conductivities less than would be desirable for optimal heat exchange. As a result, a HSHX constructed of a material having high corrosion resistance and high temperature strength (e.g., stainless steel) may have limited fin height, decreasing the area from which heat may be extracted from a waste heat source. To compensate, the width and depth of the HSHX must be increased to transfer the same amount of heat, which results in thermal mismatch between the HSHX and the thermoelectric generators of the waste heat recovery system (i.e., the ability of the thermoelectric generators to accept heat on a per area basis is greater than the ability of the HSHX to extract heat from the exhaust stream).

Because the folded fins of the HSHX of the present disclosure are formed from a composite fin material constructed of a layer of a first material (e.g., copper) positioned between layers of a second material (e.g., stainless steel), the HSHX of the present disclosure may provide both high corrosion resistance and high temperature strength (e.g., provided by the stainless steel) while maintaining high thermal conductivity (e.g., provided by the copper). As a result, the HSHX of the present disclosure, when introduced into a corrosive waste heat recovery environment (e.g., an exhaust stream), may provide better corrosion resistance and high temperature strength than certain conventional HSHXs (e.g., copper HSHXs) while maintaining a thermal conductivity sufficient to prevent thermal mismatch with the thermoelectric generators.

In certain embodiments, a thermoelectric generator (TEG)/heat exchanger array includes a hot side heat exchanger (HSHX) positioned between a first cold side heat exchanger (CSHX) and a second CSHX. The system further includes a first thermoelectric generator (TEG) having a first side in thermal communication with the HSHX and a second side in thermal communication with the first CSHX and a second TEG having a first side in thermal communication with the HSHX and a second side in thermal communication with the second CSHX. The system further includes a leaf spring clamping assembly including a first leaf spring contacting at least a portion of the first CSHX and a second leaf spring contacting at least a portion of the second CSHX. The leaf spring clamping assembly further includes first and second fasteners passing though corresponding holes at opposing ends of the first and second leaf springs such that the first and second leaf springs are loaded. The loading of the first and second leaf springs serves to maintain the thermal communication of the first TEG with the HSHX and the first CSHX and the thermal communication of the second TEG with the HSHX and the second CSHX.

Certain embodiments of the present disclosure may provide one or more technical advantages. For example, because the leaf springs of the leaf spring clamping assembly are preloaded, uniform loading is maintained across the TEGs of the array, thereby optimizing the performance of the TEGs while maintaining a compact profile. Additionally, the leaf springs allow the array to expand and contract under thermal load while maintaining uniform loading across the TEGs. In contrast, certain traditional TEG/heat exchanger arrays (e.g., those loaded with helical compression springs, Belleville washers, or rigid cross-supports) do not promote even loading of the TEGs and thus reduce the quality of the thermal interfaces between the TEGs and the heat exchangers.

Additionally, the TEG/heat exchanger array of the present disclosure may be expanded to increase overall power generation. For example, the TEG/heat exchanger array can be expanded along both the vertical axis (i.e., by placing a number of arrays side by side) and the horizontal axis (e.g., by stacking the arrays, alternating HSHXs and CSHXs) to increase the total number of TEGs. In waste heat recovery applications (e.g., from the exhaust stream of an internal combustion engine), horizontal and vertical expansion allows for greater HSHX frontal area. As a result, more heat may be extracted from the exhaust gases when they are at their hottest, thereby increasing overall power generation. Furthermore, because each stack of arrays has a single dedicated set of leaf springs, overall system weight may be minimized (which may be particularly important in automotive applications). Additionally, a number of arrays may be placed in series. In waste heat recovery applications (e.g., from the exhaust stream of an internal combustion engine), this allows for additional waste heat recovery as heat may be extracted from the exhaust stream as it passes through multiple HSHXs, allowing for more heat to be extracted from the exhaust stream.

Certain embodiments of the present disclosure may include some, all, or none of the above advantages. One or more other technical advantages may be readily apparent to those skilled in the art from the figures, descriptions, and claims included herein.

### BRIEF DESCRIPTION OF THE DRAWINGS

To provide a more complete understanding of the present disclosure and the features and advantages thereof, reference is made to the following description taken in conjunction with the accompanying drawings, in which:

FIGS. 1A-1C illustrate an example hot side heat exchanger (HSHX), according to certain embodiments of the present disclosure;

FIGS. 2A-2D illustrate a number of views of an example waste heat recovery system including the example HSHX of FIGS. 1A-1C, according to certain embodiments of the present disclosure;

FIG. 3 an example thermoelectric generator;

FIGS. 4A-4D illustrate a number of views of an example TEG/heat exchanger array, according to certain embodiments of the present disclosure;

FIGS. 5A-5C illustrate a number of views of an example three-dimensional TEG/heat exchanger array formed by replicating the TEG/heat exchanger array of FIGS. 4A-4D along the horizontal axis, according to certain embodiments of the present disclosure;

FIGS. 6A-6C illustrate a number of views of an example three-dimensional TEG/heat exchanger array formed by replicating the TEG/heat exchanger array of FIGS. 4A-4D along the horizontal axis and the vertical axis as well as placing a number of the TEG/heat exchanger arrays of FIGS. 4A-4D in series, according to certain embodiments of the present disclosure; and

FIG. 7 illustrates an assembly view of an example three-dimensional TEG/heat exchanger array, according to certain embodiments of the present disclosure.

### DETAILED DESCRIPTION OF THE DRAWINGS

In waste heat recovery systems, one or more thermoelectric generators may be positioned between a HSHX which acts as a source of thermal energy and a cold side heat exchanger (CSHX) (e.g., a cold sink or radiator) which acts as a sink for thermal energy. The HSHX may be, for example, a fin structure positioned in an exhaust stream of an internal combustion engine. The fins of the HSHX may absorb thermal energy from the exhaust stream and transfer that thermal energy into the thermoelectric generator, creating a temperature difference between the HSHX and the CSHX. As a result of this temperature difference, the one or more thermoelectric generators positioned between the HSHX and the CSHX may generate electrical energy, thereby “recovering” a portion of the energy from the waste heat source (e.g., the exhaust stream).

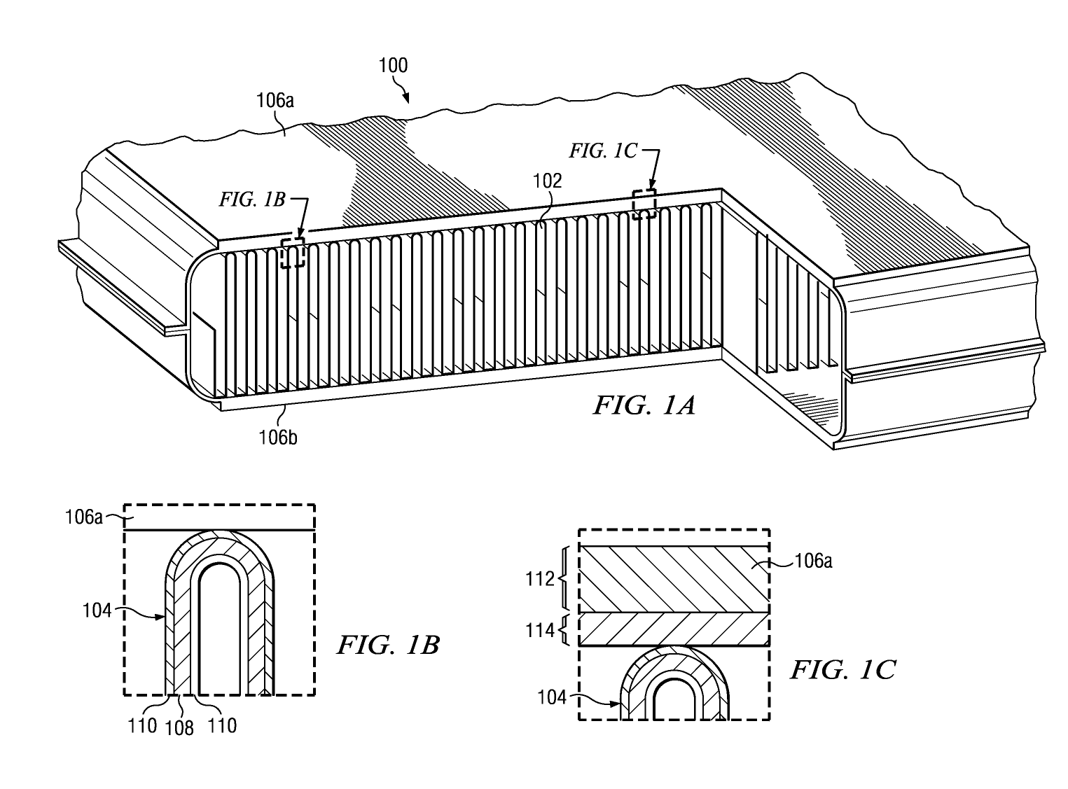

FIGS. 1A-1C illustrate an example hot side heat exchanger (HSHX) 100, according to certain embodiments of the present disclosure. HSHX 100 may include a folded fin structure 102 having a plurality of fins 104. HSHX 100 may further include base plates 106, each base plate 106 being in thermal communication with one or more of the plurality of fins 104 of folded fin structure 102. Although this particular structure of HSHX 100 is illustrated and primarily described, the present disclosure contemplates any suitable structure of HSHX 100 according to particular needs.

Fins 104 of the folded fin structure 102 of HSHX 100 may each be constructed of a composite fin material having a layer of first fin material 108 positioned between layers of a second fin material 110. In certain embodiments, the layer of first fin material 108 may be brazed to the layers of second fin material 110 or otherwise bonded to the layers of second fin material 110 in any other suitable manner. In certain other embodiments, the layers of second fin material 110 may be roll bonded to the layer of first fin material 108, clad to the layer of first fin material 108, or otherwise bonded to the layer of first fin material 108 in any other suitable manner.

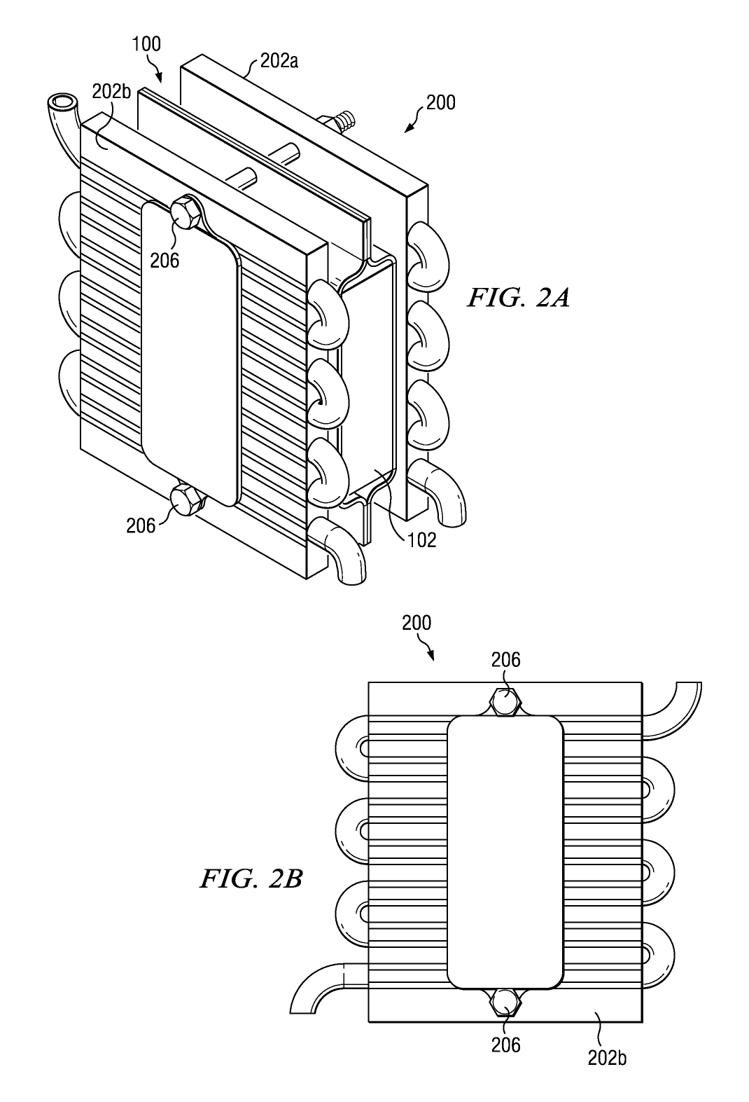

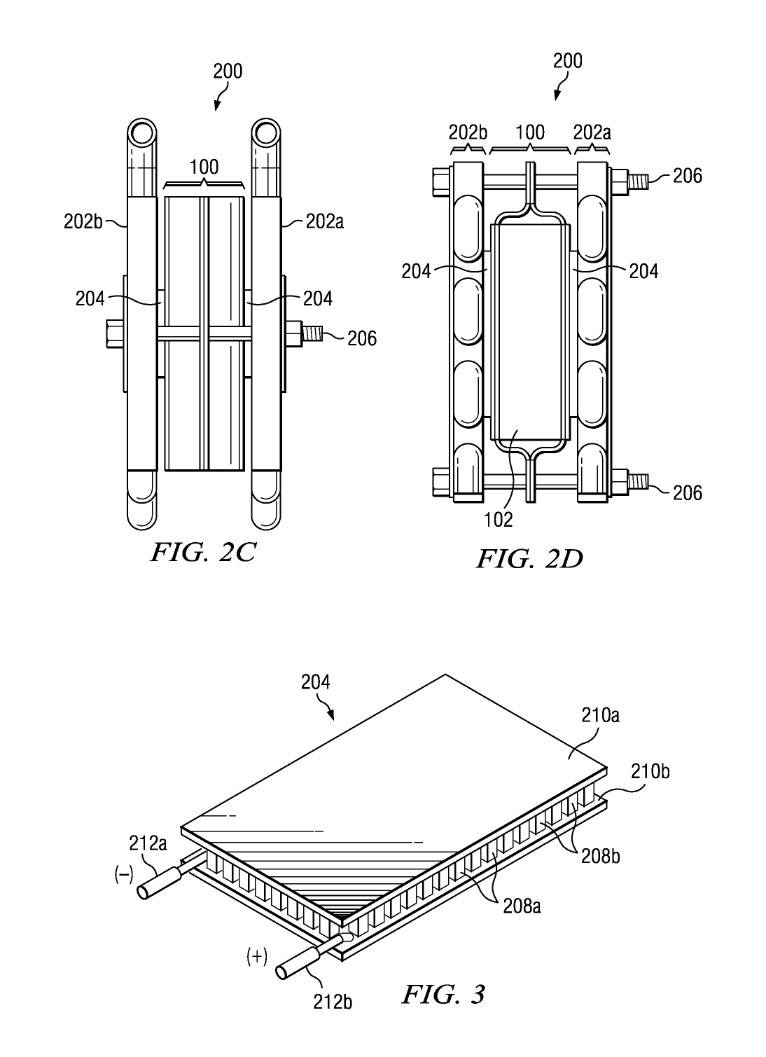

In certain embodiments, first fin material 108 may have a higher thermal conductivity than second fin material 110. Additionally, second fin material 110 may have better corrosion resistance and higher temperature strength than first fin material 108. As a result, when HSHX 100 is used to extract heat from a high temperature, corrosive environment (such as an exhaust stream of an internal combustion engine, as discussed in the context of the waste heat recovery system 200 of FIG. 2), second fin material 110 may serve to isolate first fin material 108 from the corrosive environment and maintain the rigidity of the fins 104 at high temperature. Additionally, first fin material 108 may serve to increase the overall thermal conductivity of fins 104 (as compared to fins 104 constructed solely out second fin material 110), which may allow for increased fin height and greater overall heat transfer. As a particular example, first fin material 108 may be a copper alloy having a relatively high thermal conductivity and second fin material 110 may be a stainless steel alloy having both relatively high corrosion resistance and relatively high temperature strength. In a high temperature, corrosive environment, the stainless steel alloy may prevent fins 104 from corroding while maintaining their rigidity and the copper alloy may increase the overall thermal conductivity of fins 104, allowing for increased fin height and greater heat transfer.

One or more fins 104 of HSHX 100 may be in thermal communication with base plates 106 such that heat extracted from a heat source by fins 104 may be transferred to base plates 106. Base plates 106a and 106b may be constructed of a composite base plate material including a layer of first base plate material 112 and a layer of second base plate material 114. In certain embodiments, the layer of first base plate material 112 may be brazed to the layer of second base plate material 114 or otherwise bonded to the layer of second base plate material 112 in any other suitable manner. Alternatively, the layer of second base plate material 114 may be roll bonded to the layer of first base plate material 112, clad to the layer of first base plate material 112, or otherwise bonded to the layer of first base plate material 112 in any other suitable manner.

In certain embodiments, the first base plate material 112 may be the same as first fin material 108 and second base plate material 114 may be the same material as second fin material 110 (i.e., first base plate material 112 may have a higher thermal conductivity than second base plate material 114 and second base plate material 112 may have better corrosion resistance and higher temperature strength than first base plate material 112). As a result, when HSHX 100 is used to extract heat from a high temperature, corrosive environment, second base plate material 114 may serve to isolate first base plate material 112 from the corrosive environment while helping to maintain rigidity at high temperature and first base plate material 112 may serve to increase the overall thermal conductivity of base plates 106a and 106b (as compared to based plates 106 formed solely from second base plate material 114). As a particular example, in embodiments where first fin material 108 is a copper alloy and second fin material 110 is a stainless steel alloy, first base plate material may be the same copper alloy and the second base plate material may be the same stainless steel alloy.

As a result of the above-described configuration, HSHX 100 may be well-suited for extracting heat from the exhaust stream of an internal combustion engine. As high temperature, corrosive gases of the exhaust stream travel through folded fin structure 102 of HSHX 100, the layers of second fin material 110 (e.g., stainless steel) may prevent or inhibit the corrosive gases from corroding the first fin material 108 (e.g., copper) while maintaining the rigidity of the fins 104 at high temperature. Similarly, the layer of second base plate material 114 (e.g., stainless steel) may prevent or inhibit the corrosive gases from corroding first base plate material 112 (e.g., copper) while maintaining the rigidity of the base plates 106 at high temperature. Moreover, both the first fin material 108 (e.g., copper) and the first base plate material 112 (e.g., copper) may help increase the thermal efficiency of fins 104 and base plates 106. As a result, the height of fins 104 may be increased (such that more fin area is in contact with the exhaust stream), thereby increasing the total amount of heat extracted from the exhaust stream by HSHX 100.

Although fins 104 and base plates 106 are primarily described as being constructed of a composite materials having particular configurations of particular materials (e.g., copper and stainless steel), fins 104 and base plates 106 may each be constructed of a composite materials having any suitable configuration of any suitable materials, according to particular needs. Alternatively, in certain embodiments, fins 104 and/or base plates 106 may be constructed from a non-composite material having both high temperature strength and high thermal conductivity (e.g., silicon carbide (SiC), Glidcop, or any other suitable material).

FIGS. 2A-2D illustrate a number of views of an example waste heat recovery system 200 including HSHX 100, according to certain embodiments of the present disclosure. Waste heat recovery system 200 includes HSHX 100 positioned between CSHX 202a and CSHX 202b (e.g., radiators). Additionally, positioned between base plates 106 of HSHX 100 and each CSHX 202 are one or more thermoelectric generators 204. The entire assembly is held together with a number of fasteners 206.

As fins 104 of HSHX 100 extract heat from a waste heat source (e.g., the exhaust stream of an internal combustion engine), the heat is transferred from the fins 104 to base plates 106, which in turn heats one side of each of the number of thermoelectric generators 204 in contact with the base plates 106. Furthermore, because the opposing sides of each of the number of thermoelectric generators 204 are in contact with CSHXs 202, a temperature difference is created across each of the thermoelectric generators 204. From this temperature difference, each of the thermoelectric generators 204 generates an amount of electrical energy, thereby “recovering” and amount of the heat energy from the waste heat source.

FIG. 3 illustrates a more detailed view of a thermoelectric generator 204 that may be used in waste heat recovery system 200. Thermoelectric generator 204 generally includes a plurality of P-type and N-type thermoelectric elements 208 disposed between a first plate 210a and a second plate 210b (collectively, plates 210). Electrical connectors 212a and 212b (collectively, electrical connectors 212) are provided to allow electrical power to be drawn from thermoelectric generator 204 when thermoelectric generator 204 is subjected to a temperature difference, as mentioned above.

Ceramic materials are frequently used to manufacture plates 210. However, in particular embodiments, either or both of plates 210 may be composed of a flexible material such as polyimide. In particular embodiments, thermoelectric elements 208 may be formed from bismuth telluride (Bi₂, Te₃) alloys, or other suitable thermoelectric materials.

The ends of thermoelectric elements 208 are electrically connected to one another by a series of electrical interconnects composed of an electrically and thermally conductive material such as copper. Depending upon design, the electrical interconnects may be a patterned metallization formed on the interior surfaces of plates 210 using any suitable deposition process. Also, depending upon the composition of elements 208 and the electrical interconnects, a diffusion barrier metallization may be applied to the ends of elements 208 to provide a surface for soldering and to prevent chemical reactions from occurring between the electrical interconnects and elements 208. For example, the diffusion barrier may be needed if the electrical interconnects are composed of copper and thermoelectric elements 208 are composed of a bismuth telluride alloy. The diffusion barrier may comprise nickel or other suitable barrier material (e.g., molybdenum).

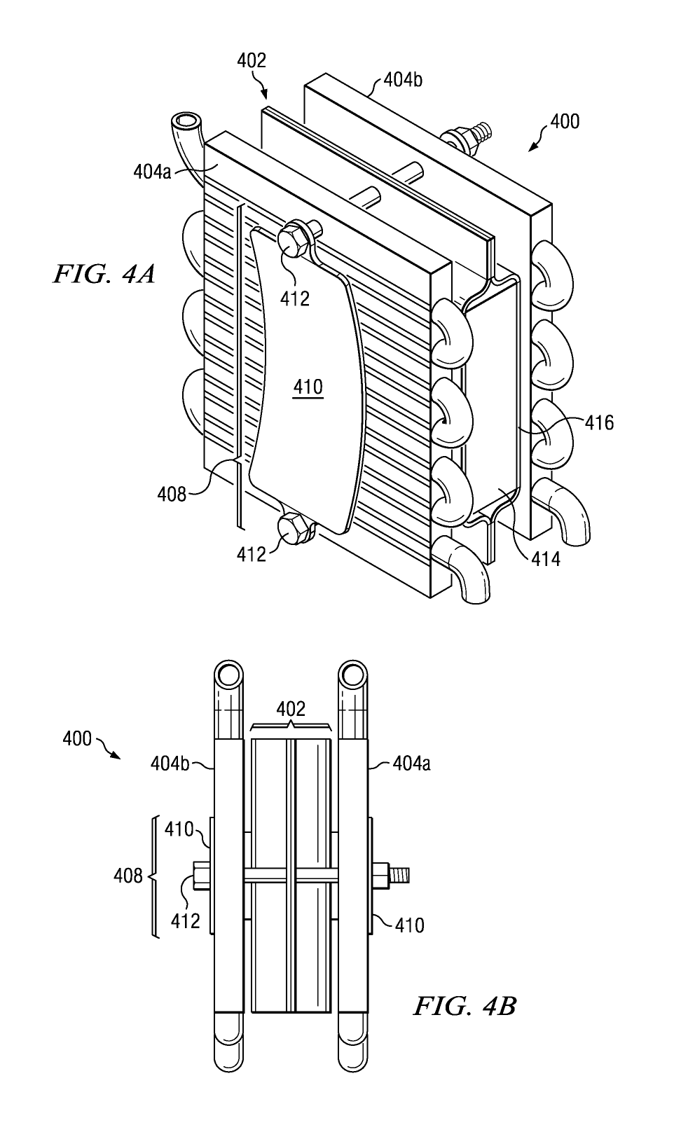

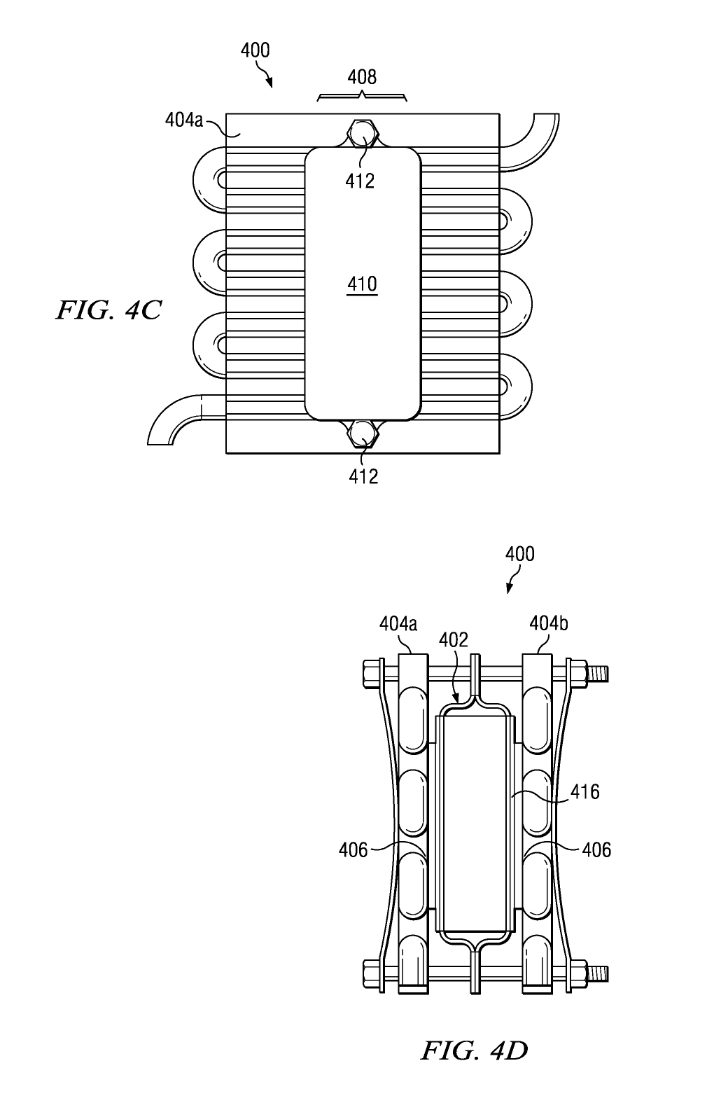

FIGS. 4A-4D illustrate a number of views of an example thermoelectric generator (“TEG”)/heat exchanger array 400 (hereinafter referred to as “array 400”), according to certain embodiments of the present disclosure. Array 400 may include a HSHX 402, CSHXs 404a and 404b, and a plurality of TEGs 406. A first one or more of the plurality TEGs 406 may be position between HSHX 402 and CSHX 404a such that a first side of each is in thermal communication with HSHX 402 and a second side of each is in thermal communication with CSHX 404a. A second one or more of the plurality TEGs 406 may be position between HSHX 402 and CSHX 404b such that a first side of each is in thermal communication with HSHX 402 and a second side of each is in array 400 may be held together by a clamping assembly 408 including leaf springs 410 and fasteners 412. Although this particular implementation of system 400 is illustrated and primarily described, the present disclosure contemplates any suitable implementation of system 400 according to particular needs.

HSHX 402 may be designed to extract heat from a heat source. For example, in a waste heat recover application, HSHX 402 may be configured to receive a stream of heated gas (e.g., an exhaust steam of an internal combustion engine), the heated gas passing through a folded fin structure 414 of HSHX 402. Fins of the folded fin structure 414 may extract heat from the stream of gas and transfer the extracted heat to opposing surfaces 416 of HSHX 402. Because a surface of one or more TEGs 406 is in thermal communication with surfaces 416 of HSHX 402, the heat extracted from the stream of gas heats the surface of the one or more TEGs 406. Furthermore, because the opposing surfaces of TEGs 406 are in thermal communication with CSHXs 404 (e.g., cold sinks or radiators), a temperature difference is created across each of the TEGs 406. From this temperature difference, TEGs 406 generate electrical energy.

Array 400 may be held together with a clamping assembly 408 comprising leaf springs 410 each contacting at least a portion of the outer surfaces of CSHX 404a and 404b. Fasteners 412 may pass though corresponding holes at opposing ends of the leaf springs 410 such that leaf springs 410 are loaded. This loading of leaf springs 410 may serve to maintain the above-described thermal communication between TEGs 406, HSHX 402, and CSHXs 404. Leaf springs 410 may also help to maintain more uniform loading across each TEG 406 than certain previous systems (e.g., assemblies having rigid compression members subjected to end loading or bolting that deflect and place an uneven edge load on TEGs). Additionally, leaf springs 410 may allow array 400 to expand and contract under thermal load while maintaining uniform loading across TEGs 406. By providing uniform loading across TEGs 406, the thermal interfaces between TEGs 406, HSHX 402, and CSHXs 404 may be optimized, thereby increasing the performance of TEGs 406.

In certain embodiment, each leaf spring 410 may include one of more “bumps” positioned at locations corresponding to each of the one or more TEGs 406. Each bump may center the load provided by leaf spring 410 directly over a TEG 406. By centering the load directly over each TEG 406, the thermal interfaces between TEGs 406, HSHX 402, and CSHXs 404 may be further optimized, thereby further increasing the performance of TEGs 406.

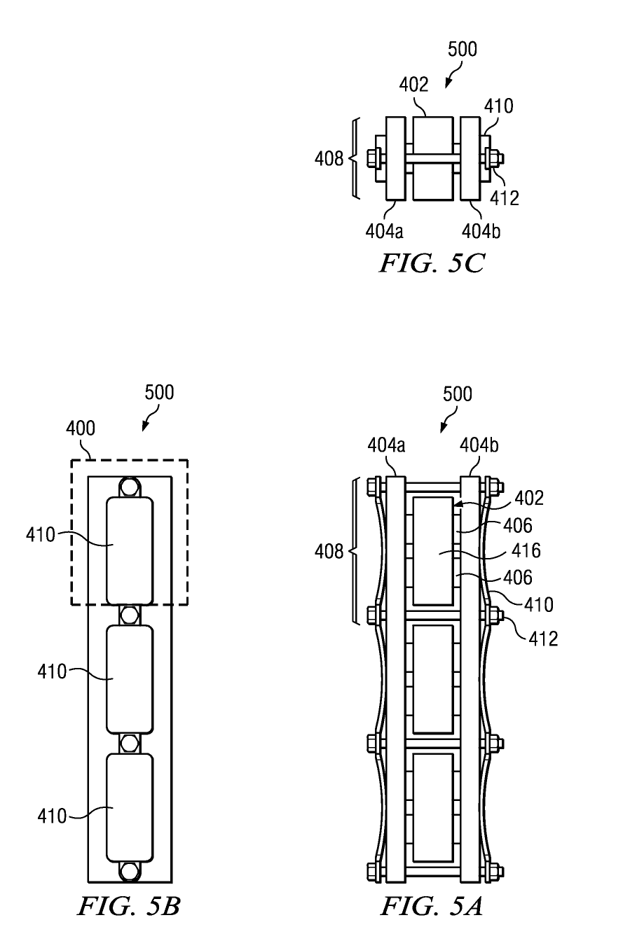

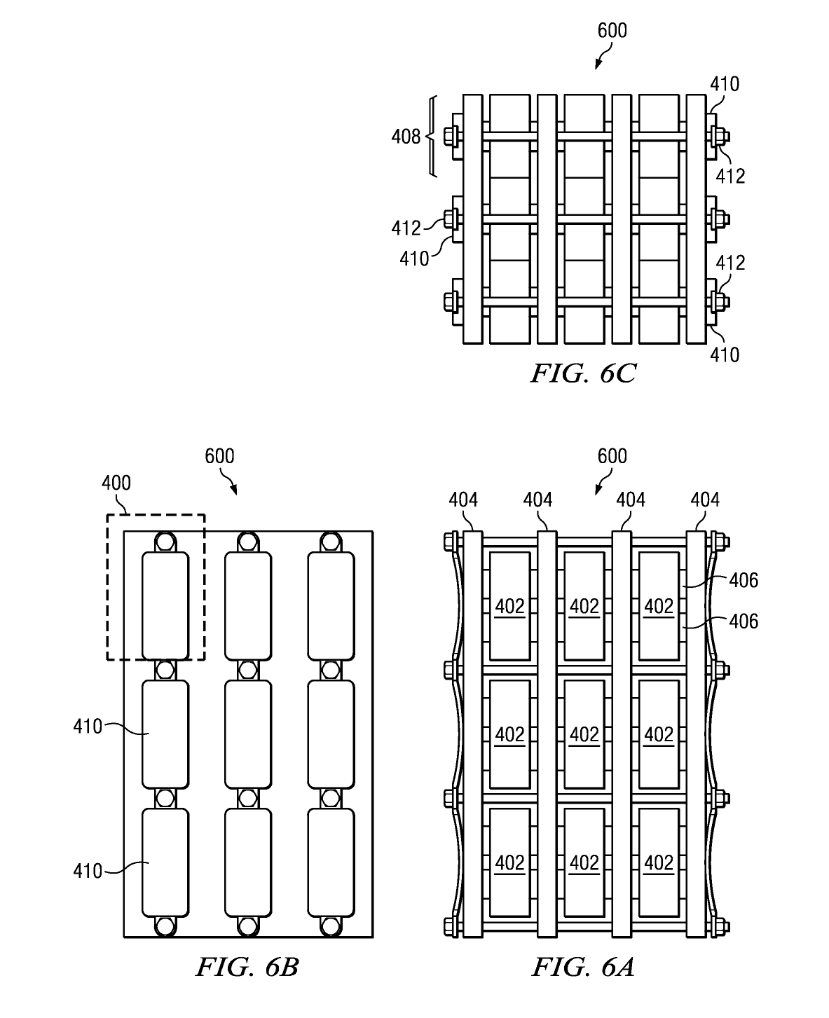

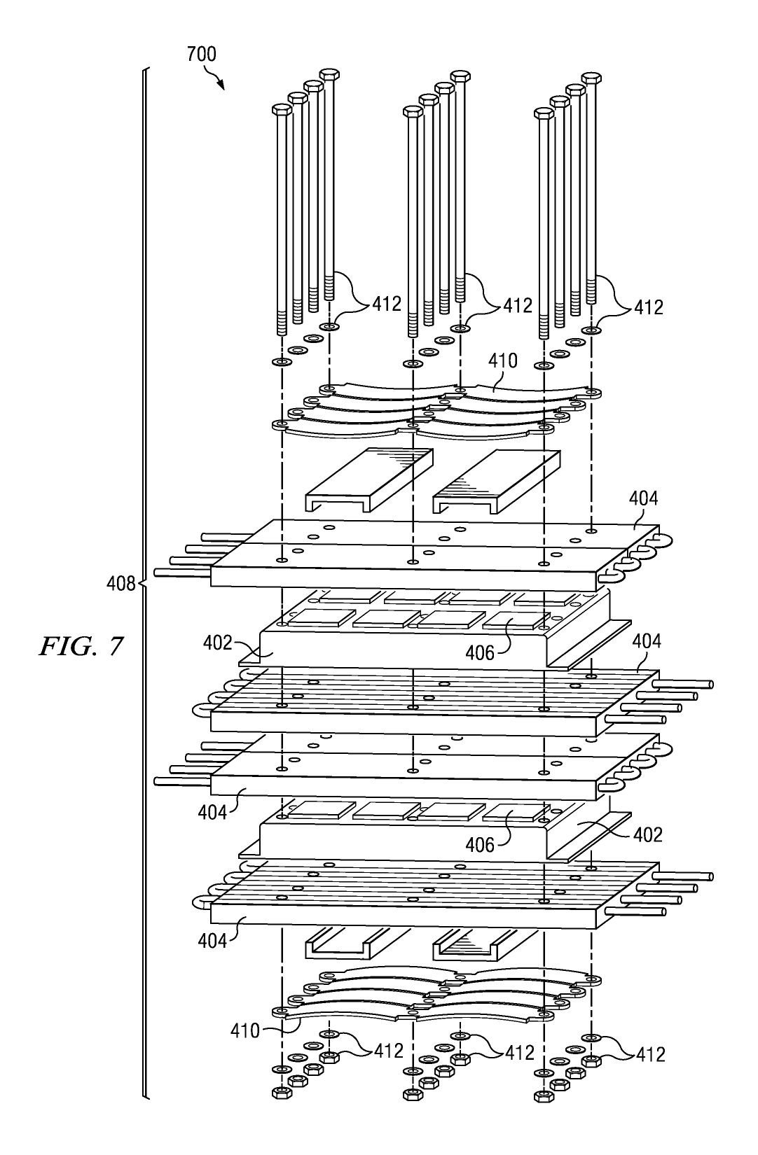

Due the above-described configuration of array 400, array 400 may be replicated along the horizontal and/or the vertical axis to create a three-dimensional array (such as array 500 illustrated in FIGS. 5A-5C, array 600 illustrated in FIGS. 6A-6C, and array 700 illustrated in FIG. 7, each of which is described in further detail below).

Although the components of system 400 are illustrated and primarily described as having particular configurations, the present disclosure contemplates the components of array 400 having any suitable configurations, according to particular needs.

FIGS. 5A-5C illustrate a number of views of an example three-dimensional TEG/heat exchanger array 500 (hereinafter referred to as “3-D array 500”) formed by replicating array 400 along the horizontal axis, according to certain embodiments of the present disclosure. Each array 400 of 3-D array 500 may include a dedicated pair of leaf springs 410 (as opposed to a set of longer leaf springs 410) such that uniform loading may be maintained across each of the TEGs 406 of each array 400. In certain embodiments, each CSHX 404 of 3-D array 500 may be a continuous radiator structure (i.e., each CSHX 404 of 3-D array 500 may be part of multiple arrays 400 rather than each array 400 having a dedicated pair of CSHXs 404) having holes corresponding to each of the fasteners 412 of the clamping assemblies 408 of each array 400. These “solid” CSHXs 404 may help add structural rigidity to 3-D array 500.

In waste heat recovery applications (e.g., from the exhaust stream of an internal combustion engine), an exhaust stream may be distributed among the number of HSHXs 402 of 3-D array 500 via a manifold structure. As a result, the overall HSHX frontal area is increased, allowing more heat to be extracted from the exhaust gases when they are at their hottest and increasing overall power generation by the number of TEGs 406.

FIGS. 6A-6C illustrate a number of views of an example three-dimensional TEG/heat exchanger array 600 (hereinafter referred to as “3-D array 600”) formed by replicating array 400 along the horizontal axis and the vertical axis as well as placing a number of arrays 400 in series, according to certain embodiments of the present disclosure. In other words, 3-D array 600 may formed by replicating array 400 in the manner described with regard to FIGS. 5A-5C (horizontal expansion) as well as stacking arrays 400 (vertical expansion—alternating HSHX 402 and CSHX 404) and placing arrays 400 in series.

Each set of stacked arrays 400 of 3-D array 600 may dedicated pair of leaf springs 410 (as opposed to a set of longer leaf springs 410) such that uniform loading may be maintained across each of the TEGs 406 of each array 400. Moreover, because each set of leaf springs 400 maintains uniform loading for TEGs 406 of each stacked array 400, the overall weight of 3-D array 600 may be minimized (which may be particularly important in automotive applications). In certain embodiment, each CSHX 404 of 3-D array 600 may be a continuous radiator structure (i.e., each CSHX 404 of 3-D array 600 may be part of multiple arrays 400 rather than each array 400 having a dedicated pair of CSHXs 404) having holes corresponding to each of the fasteners 412 of the clamping assemblies 408 of each array 400. These “solid” CSHXs 404 may help add structural rigidity to 3-D array 500.

In waste heat recovery applications (e.g., from the exhaust stream of an internal combustion engine), an exhaust stream may be distributed among the number of HSHXs 402 of 3-D array 500 via a manifold structure. As a result, the overall HSHX frontal area is increased, allowing more heat may to be extracted from the exhaust gases when they are at their hottest and increasing overall power generation by the number of TEGs 406. Additionally, because a number of arrays 400 are placed in series, additional downstream heat may be extracted from the exhaust stream as it passes through the additional HSHXs 402, allowing for more heat to be extracted from the exhaust stream and further increasing overall power generation by the number of TEGs 406.

FIG. 7 illustrates an assembly view of example three-dimensional TEG/heat exchanger array 700, according to certain embodiments of the present disclosure.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended example claims.

What is claimed is:

1. A system comprising:
a hot side heat exchanger (HSHX), the HSHX comprising:
a plurality of fins, each of the plurality fins being formed from a composite fin material having a first fin layer positioned between a second fin layer and a third fin layer, the first fin layer being a first material and the second and third fin layers being a second material; and
a first base plate in thermal communication with the plurality of fins; and
wherein the first material has a greater thermal conductivity than the second material and the second material has greater corrosion resistance and higher temperature strength than the first material.

2. The system of claim 1, wherein the first base plate comprises a composite base plate material having a first base plate layer and a second base plate layer, the first base plate layer being the first material and the second base plate layer being the second material.

3. The system of claim 1, wherein:
the first material comprises copper; and
the second material comprises stainless steel.

4. The system of claim 1, wherein the composite fin material is formed by cladding the first fin layer with the second and third fin layers.

5. The system of claim 1, further comprising a thermoelectric generator in thermal communication with the first base plate such that the thermoelectric generator generates electrical energy from heat extracted by the HSHX.

6. The system of claim 1, wherein the plurality of fins are arranged in a folded fin structure.

7. The system of claim 1, further comprising:
a first thermoelectric generator in thermal communication with the first base plate; and
a first cold side heat exchanger (CSHX) in thermal communication with the first thermoelectric generator arranged such that the first thermoelectric generator is positioned between the first base plate and the first CSHX.

8. The system of claim 7, wherein the HSHX comprises a second base plate and further comprising:
a second thermoelectric generator in thermal communication with the second base plate; and
a second cold side heat exchanger (CSHX) in thermal communication with the second thermoelectric generator arranged such that the second thermoelectric generator is positioned between the second base plate and the second HSHX.

9. The system of claim 1, wherein the HSHX is operable to extract heat from a heated stream.

10. A method comprising:
forming a plurality of fins, each of the plurality fins formed using a composite fin material having a first fin layer positioned between a second fin layer and a third fin layer, the first fin layer being a first material and the second and third fin layers being a second material;
forming a first base plate;
placing the first base plate in thermal communication with the plurality of fins; and
wherein the first material has a greater thermal conductivity than the second material and the second material has greater corrosion resistance and higher temperature strength than the first material.

11. The method of claim 10, wherein the first base plate is formed using a composite base plate material having a first base plate layer and a second base plate layer, the first base plate layer being the first material and the second base plate layer being the second material.

12. The method of claim 10, wherein:
the first material comprises copper; and
the second material comprises stainless steel.

13. The method of claim 10, further comprising cladding the first fin layer with the second and third fin layers.

14. The method of claim 10, further comprising arranging the plurality of fins in a folded fin structure.

15. The method of claim 10, further comprising:
placing a first thermoelectric generator in thermal communication with the first base plate; and
placing a first cold side heat exchanger (CSHX) in thermal communication with the first thermoelectric generator such that the first thermoelectric generator is positioned between the first base plate and the first CSHX

16. The method of claim 15, further comprising:
placing a second thermoelectric generator in thermal communication with a second base plate; and
placing a second cold side heat exchanger (CSHX) in thermal communication with the second thermoelectric generator such that the second thermoelectric generator is positioned between the second base plate and the second CSHX.

17. The method of claim 10, further comprising placing a thermoelectric generator in thermal communication with the first base plate.

18. The method of claim 17, further comprising:
extracting heat by the plurality of fins; and
generating electrical energy by the thermoelectric generator from the extracted heat.

19. The method of claim 18, wherein the heat is extracted from a heated stream.

20. A method comprising:
extracting heat by a plurality of fins, each of the plurality fins comprising a composite fin material having a first fin layer positioned between a second fin layer and a third fin layer, the first fin layer being a first material and the second and third fin layers being a second material;
transferring the extracted heat to a first base plate; and
wherein the first material has a greater thermal conductivity than the second material and the second material has greater corrosion resistance and higher temperature strength than the first material.

21. The method of claim 20, wherein the first base plate comprises a composite base plate material having a first base plate layer and a second base plate layer, the first base plate layer being the first material and the second base plate layer being the second material.

22. The method of claim 20, wherein:
the first material comprises copper; and
the second material comprises stainless steel.

23. The method of claim 20, wherein the plurality of fins are arranged in a folded fin structure.

24. The method of claim 20, further comprising generating electrical energy by a thermoelectric generator from the extracted heat.

25. The method of claim 20, wherein the heat is extracted from a heated stream.
